(19) United States
(12) Patent Application Publication
(10) Pub. No.: US 2025/0160122 A1
(43) Pub. Date: May 15, 2025

(54) DISPLAY APPARATUS AND METHOD OF MANUFACTURING THE SAME

(71) Applicant: Samsung Display Co., Ltd., Yongin-si (KR)

(72) Inventors: Keunwoo Kim, Yongin-si (KR); Sangsub Kim, Yongin-si (KR); Bummo Sung, Yongin-si (KR); Kyoungseok Son, Yongin-si (KR); Hyuneok Shin, Yongin-si (KR); Sunhee Lee, Yongin-si (KR); Sanggun Choi, Yongin-si (KR); Taehyun Hong, Yongin-si (KR)

(73) Assignee: Samsung Display Co., Ltd., Yongin-si (KR)

(21) Appl. No.: 18/788,505

(22) Filed: Jul. 30, 2024

(30) Foreign Application Priority Data
Nov. 10, 2023 (KR) 10-2023-0155723

(51) Int. Cl. H10K 59/121; H10K 59/12

(52) U.S. Cl. CPC H10K 59/1213; H10K 59/1201

(57) ABSTRACT

Provided is a display apparatus including a substrate, a first semiconductor layer disposed on the substrate and including a first active portion, a second active portion, and a first doped portion, a first conductive layer including a first conductive pattern overlapping the first active portion, a second conductive layer including a second conductive pattern and a third conductive pattern, the second conductive pattern overlapping the first conductive pattern, and the third conductive pattern connected to the first doped portion through a first contact hole, a second semiconductor layer disposed on the second conductive layer, and including an upper-first active portion and a second doped portion, a third conductive layer including a first conductive line overlapping the upper-first active portion, and a fourth conductive layer including a fourth conductive pattern electrically connecting the third conductive pattern to the second doped portion.

### CROSS-REFERENCE TO RELATED APPLICATION(S)

This application claims priority to and benefits of Korean Patent Application No. 10-2023-0155723 under 35 U.S.C. § 119, filed on Nov. 10, 2023, in the Korean Intellectual Property Office, the entire contents of which are incorporated herein by reference.

### BACKGROUND

### 1. Technical Field

One or more embodiments relate to a display apparatus and a method of manufacturing the display apparatus.

### 2. Description of the Related Art

Generally, a display apparatus includes light-emitting diodes and thin-film transistors that control brightness and the like of the light-emitting diodes. The thin-film transistors control corresponding light-emitting diodes to emit light of a preset color by using a data signal, a driving voltage, and a common voltage transferred thereto.

### SUMMARY

One or more embodiments include a display apparatus that provides high-quality images and a method of manufacturing the display apparatus. However, such a technical objective is just an example, and embodiments are not limited thereto.

Additional aspects will be set forth in part in the description which follows and, in part, will be apparent from the description, or may be learned by practice of the embodiments.

According to one or more embodiments, a display apparatus may include a substrate, a first semiconductor layer disposed on the substrate and including a first active portion, a second active portion, and a first doped portion between the first active portion and the second active portion, a first conductive layer disposed on the first semiconductor layer and including a first conductive pattern overlapping the first active portion, a second conductive layer disposed on the first conductive layer and including a second conductive pattern and a third conductive pattern, the second conductive pattern overlapping the first conductive pattern, the third conductive pattern connected to the first doped portion through a first contact hole exposing a portion of the first doped portion, a second semiconductor layer disposed on the second conductive layer and including an upper-first active portion and a second doped portion extending from the upper-first active portion, a third conductive layer disposed on the second semiconductor layer, and including a first conductive line overlapping the upper-first active portion, and a fourth conductive layer disposed on the third conductive layer and including a fourth conductive pattern electrically connecting the third conductive pattern to the second doped portion.

The first semiconductor layer may further include a fourth active portion and a third doped portion between the first active portion and the fourth active portion, and the first conductive layer may further include a second conductive line extending in a first direction and overlapping the second active portion and the fourth active portion.

The first semiconductor layer may further include a fifth active portion extending from the third doped portion to be farther away from the fourth active portion, and the first conductive layer may further include a third conductive line extending in the first direction and overlapping the fifth active portion.

The first semiconductor layer may further include a fourth doped portion extending from the fifth active portion to be farther away from the third doped portion, and the fourth doped portion may be electrically connected to a data line.

The second conductive layer may further include a fourth conductive line extending in a first direction and overlapping the upper-first active portion.

The first conductive line and the fourth conductive line may overlap each other.

The first semiconductor layer may further include a sixth active portion, and a fifth doped portion and a sixth doped portion respectively extending to sides of the sixth active portion, and

The first conductive layer may further include a fifth conductive line extending in the first direction and overlapping the sixth active portion.

The second semiconductor layer may further include an upper-second active portion and a seventh doped portion between the upper-first active portion and the upper-second active portion, and the third conductive layer may further include a sixth conductive line extending in a first direction and overlapping the upper-second active portion.

The first semiconductor layer may include a silicon semiconductor material, and the second semiconductor layer may include an oxide-based semiconductor material.

The fourth conductive pattern may be connected to the third conductive pattern through a second contact hole exposing a portion of the third conductive pattern, the first contact hole may be spaced apart from the second contact hole by a first distance, and the first distance may be in a range of about 1 μm to about 2 μm.

According to one or more embodiments, a method of manufacturing a display apparatus may include forming a first semiconductor layer over a substrate, forming a first insulating layer on the first semiconductor layer, forming, on the first insulating layer, a first conductive layer including a first gate electrode overlapping the first semiconductor layer, and doping the first semiconductor layer, forming a second insulating layer on the first conductive layer, forming a first contact hole exposing a portion of the first semiconductor layer, and heat-treating the first semiconductor layer, forming, on the second insulating layer, a capacitor electrode overlapping the first gate electrode and a second conductive layer including a first connection electrode overlapping the first contact hole, forming a third insulating layer on the second conductive layer, and forming a second semiconductor layer on the third insulating layer.

The first semiconductor layer may include a first active region, and a first doped region and a second doped region respectively extending to sides of the first active region, wherein the first active region may overlap the first gate electrode, and in the forming of the first contact hole and the heat-treating of the first semiconductor layer, the first contact hole may be formed to overlap the first doped region.

The method may further include forming a fourth insulating layer on the second semiconductor layer, forming, on the fourth insulating layer, a third conductive layer including a second gate electrode overlapping the second semiconductor layer, forming a fifth insulating layer on the third conductive layer, forming a second contact hole, a third contact hole, and a fourth contact hole, the second contact hole exposing a portion of the first connection electrode, the third contact hole exposing a portion of the second doped region of the first semiconductor layer, and the fourth contact hole exposing a portion of the second semiconductor layer, and forming, on the fifth insulating layer, a fourth conductive layer including a first source-drain electrode overlapping the second contact hole, a second source-drain electrode overlapping the third contact hole, a third source-drain electrode overlapping the fourth contact hole.

The forming of the second contact hole, the third contact hole, and the fourth contact hole may include simultaneously forming the second contact hole and the third contact hole, and after the forming of the second contact hole and the third contact hole, forming the fourth contact hole.

The second contact hole, the third contact hole, and the fourth contact hole may be simultaneously formed.

The first contact hole may be spaced apart from the second contact hole by a first distance, and the first distance may be about 1 μm to about 2 μm.

In the forming of the first contact hole and the heat-treating of the first semiconductor layer, a fifth contact hole overlapping the second doped region may be simultaneously formed with the first contact hole, and in the forming of the second conductive layer, the second conductive layer may further include a second connection electrode overlapping the fifth contact hole.

The method may further include forming a fourth insulating layer covering the second semiconductor layer, forming, on the fourth insulating layer, a third conductive layer including a second gate electrode overlapping the second semiconductor layer, forming a fifth insulating layer on the third conductive layer, forming a second contact hole exposing a portion of the first connection electrode, a third contact hole exposing a portion of the second connection electrode, and a fourth contact hole exposing a portion of the second semiconductor layer, and forming, on the fifth insulating layer, a fourth conductive layer including a first source-drain electrode overlapping the second contact hole, a second source-drain electrode overlapping the third contact hole, and a third source-drain electrode overlapping the fourth contact hole.

The second contact hole, the third contact hole, and the fourth contact hole may be simultaneously formed.

The first semiconductor layer may include a silicon semiconductor material, and the second semiconductor layer may include an oxide-based semiconductor material.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic plan view of a display apparatus according to an embodiment;

FIG. 2 is a schematic diagram of an equivalent circuit of a pixel of a display apparatus according to an embodiment;

FIG. 3 is a schematic cross-sectional view of a display apparatus according to an embodiment;

FIG. 4 is a schematic cross-sectional view of a display apparatus according to another embodiment;

FIGS. 5A, 5B, 5C, 5D, 5E, and 5F are schematic cross-sectional views for explaining some operations of a method of manufacturing a display apparatus according to an embodiment;

FIG. 6 is a schematic layout view of a display apparatus according to an embodiment illustrating an area B of FIG. 1;

FIGS. 7A, 7B, 7C, 7D, 7E, 7F, and 7G are schematic layout views of each layer of a display apparatus according to an embodiment illustrating the area B of FIG. 1; and

FIG. 8 is a schematic cross-sectional view of a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the description, the term “about” or “approximately” includes the stated value and may indicate an allowable range of deviation determined by taking into account errors related to the manufacturing method or measurement method with respect to the stated value. As an example, in the description, the term about may mean within ±20%, ±10%, or ±5% of the specified value.

In the case where a certain embodiment may be implemented differently, a specific process order may be performed in the order different from the described order. As an example, two processes successively described may be simultaneously performed substantially and performed in the opposite order.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

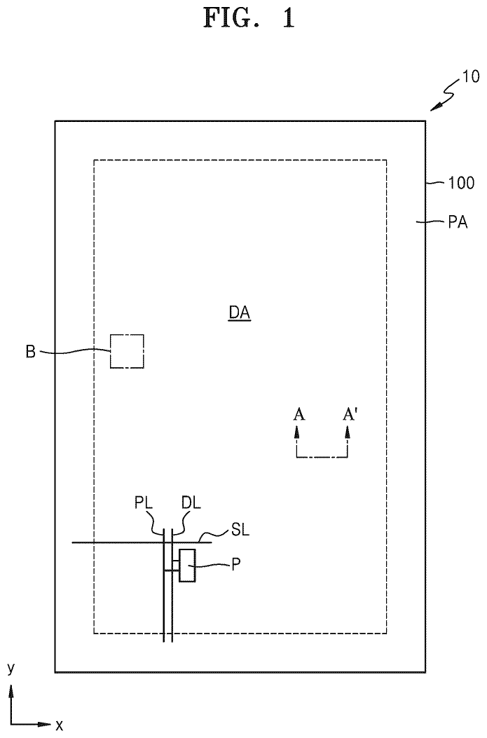

FIG. 1 is a schematic plan view of a display apparatus 10 according to an embodiment.

Referring to FIG. 1, the display apparatus 10 may include a display area DA that displays images and a peripheral area PA arranged around the display area DA.

The display apparatus 10 may include a substrate 100. In the description, in case that the substrate 100 includes a display area DA and the peripheral area PA, the substrate 100 may include a region overlapping the display area DA and a region overlapping the peripheral area PA.

The substrate 100 may include a glass material, a ceramic material, metal, plastic, or a flexible or bendable material. In the case where the substrate 100 is flexible or bendable, the substrate 100 may include a polymer resin including polyethersulphone (PES), polyacrylate, polyetherimide (PEI), polyethylene naphthalate (PEN), polyethylene terephthalate (PET), polyphenylene sulfide (PPS), polyarylate, polyimide (PI), polycarbonate (PC), and cellulose acetate propionate (CAP).

Pixels P each including a display element such as a light-emitting diode may be arranged in the display area DA of the substrate 100. The light-emitting diode may include an organic light-emitting diode including an organic emission layer. In another example, the light-emitting diode may be an inorganic light-emitting diode including an inorganic emission layer. The size of the light-emitting diode may be microscales or nanoscales.

Each pixel P may include a pixel circuit electrically connected to a light-emitting diode. The pixel circuit may include transistors and a storage capacitor. The pixel circuits may each be electrically connected to peripheral circuits arranged in the peripheral area PA. As an example, the pixel circuit may be connected to a scan line SL, a data line DL crossing the scan line SL, and a driving voltage line PL. The scan line SL may extend in a first direction (e.g., x-axis direction), and the data line DL and the driving voltage line PL may extend in a second direction (e.g., y-axis direction) crossing the first direction (e.g., x-axis direction).

The display apparatus 10 may display images by using light emitted from the pixels P. Each pixel P may emit, for example, red light, green light, or blue light. The pixels P may be arranged in various configurations such as a stripe configuration, a pentile configuration, a mosaic configuration, and the like in the display area DA to display images.

The peripheral area PA may be a region in which the pixels P are not arranged and may be a region that does not display images. The peripheral area PA may be arranged outside the display area DA to surround the display area DA. A printed circuit board, a terminal part, and the like may be arranged in the peripheral area PA. The printed circuit board may include a built-in driving circuit, a power supply line, and a driving circuit that drives the pixels P, and a driver integrated circuit (IC) may be connected to the terminal part.

In an embodiment, the display area DA may have a rectangular shape in which a length in the first direction (e.g., x-axis direction) is less than a length in the second direction (e.g., y-axis direction). In another embodiment, the display area DA may be formed in a polygonal shape such as a triangle, a pentagon, a hexagon, and the like, a circular shape, an elliptical shape, an irregular shape, or the like. The display area DA may have round corners.

The display apparatus 10 may be an apparatus for displaying moving images or still images and may include portable electronic apparatuses such as mobile phones, smartphones, tablet personal computers, mobile communication terminals, electronic organizers, electronic books, portable multimedia players (PMPs), navigations, and ultra mobile personal computers (UMPCs), and the like. In another example, the display apparatus 10 may be used as a display screen of various products including televisions, notebook computers, monitors, advertisement boards, Internet of things (IoTs), and the like. For example, the display apparatus 10 according to an embodiment may be used in wearable devices including smartwatches, watchphones, glasses-type displays, and head-mounted displays (HMDs). For example, the display apparatus 10 according to an embodiment may be used as instrument panels for automobiles, center fascias for automobiles, or center information displays (CID) arranged on a dashboard, room mirror displays that replace side mirrors of automobiles, and displays arranged on the backside of front seats as an entertainment for back seats of automobiles.

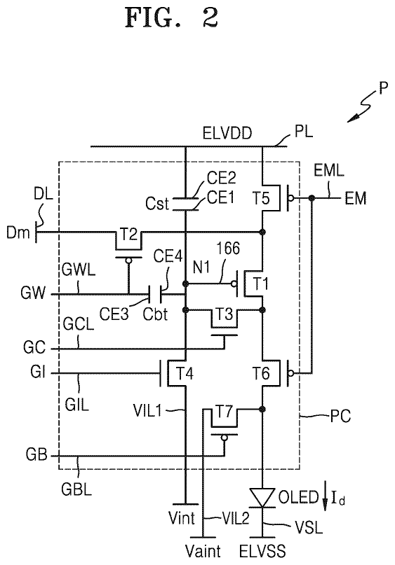

FIG. 2 is a schematic diagram of an equivalent circuit of a pixel P of a display apparatus 10 according to an embodiment.

Referring to FIG. 2, the pixel P may include an organic light-emitting diode OLED, as a display element, and a pixel circuit PC electrically connected to the organic light-emitting diode OLED. The pixel circuit PC may include seven transistors and at least one capacitor. As an example, the pixel circuit PC may include first to seventh transistors T1, T2, T3, T4, T5, T6, and T7, a storage capacitor Cst, and a boost capacitor Cbt. In another embodiment, the pixel circuit PC may not include the boost capacitor Cbt.

Each of the first to seventh transistors T1, T2, T3, T4, T5, T6, and T7, the storage capacitor Cst, and the boost capacitor Cbt may be connected to signal lines, a first initialization voltage line VIL1, a second initialization voltage line VIL2, the driving voltage line PL, and a common voltage line VSL. The signal lines may include a data line DL, a first scan line GWL, a second scan line GCL, a third scan line GIL, a fourth scan line GBL, and an emission control line EML. The first scan line GWL may transfer a first scan signal GW, the second scan line GCL may transfer a second scan signal GC, the third scan line GIL may transfer a third scan signal GI, the fourth scan line GBL may transfer a fourth scan signal GB, and the emission control line EML may transfer an emission control signal EM. In an embodiment, the signal lines, the first initialization voltage line VIL1, the second initialization voltage line VIL2, the driving voltage line PL, and the common voltage line VSL may be shared by adjacent pixel circuits.

The driving voltage line PL may transfer a first power voltage ELVDD to the first transistor T1. The first initialization voltage line VIL1 may transfer a first initialization voltage Vint to the pixel circuit PC. The first initialization voltage Vint may initialize the first transistor T1. The second initialization voltage line VIL2 may transfer a second initialization voltage Vaint to the pixel circuit PC. The second initialization voltage Vaint may initialize the organic light-emitting diode OLED. The common voltage line VSL may transfer a second power voltage ELVSS to an opposite electrode (e.g., a cathode) of the organic light-emitting diode OLED.

Each of the first to seventh transistors T1, T2, T3, T4, T5, T6, and T7 may include a gate electrode, a first terminal, and a second terminal, and one of the first terminal and the second terminal may function as a source, and the other may function as a drain.

The first transistor T1 may be a driving transistor. A first gate electrode of the first transistor T1 may be connected to the storage capacitor Cst, a first terminal of the first transistor T1 may be electrically connected to the driving voltage line PL through the fifth transistor T5, and a second terminal of the first transistor T1 may be electrically connected to a pixel electrode (e.g., anode) of the organic light-emitting diode OLED through the sixth transistor T6. The first transistor T1 may supply a driving current I_{d} to the organic light-emitting diode OLED according to a switching operation of the second transistor T2.

The second transistor T2 may be a data-write transistor. A second gate electrode of the second transistor T2 may be connected to the first scan line GWL, a first terminal of the second transistor T2 may be connected to the data line DL, and a second terminal of the second transistor T2 may be connected to the first terminal of the first transistor T1. The second transistor T2 may be turned on according to a first scan signal GW transferred through the first scan line GWL and may perform a switching operation to transfer a data signal Dm to the first terminal of the first transistor T1. The data signal Dm may be transferred through the data line DL.

The third transistor T3 may be a compensation transistor that compensates for a threshold voltage of the first transistor T1. A third gate electrode of the third transistor T3 may be connected to the second scan line GCL. A first terminal of the third transistor T3 may be connected to a first capacitor electrode CE1 of the storage capacitor Cst and the first gate electrode of the first transistor T1 through a node connection line 166. A first terminal of the third transistor T3 may be connected to the fourth transistor T4. A second terminal of the third transistor T3 may be connected to the second terminal of the first transistor T1 and electrically connected to a pixel electrode (e.g., anode) of the organic light-emitting diode OLED through the sixth transistor T6. The third transistor T3 may be turned on according to a second scan signal GC transferred through the second scan line GCL, and diode-connects the first transistor T1 by electrically connecting the first gate electrode to the second terminal (e.g., drain electrode) of the first transistor T1.

The fourth transistor T4 may be a first initialization transistor that initializes the first gate electrode of the first transistor T1. A fourth gate electrode of the fourth transistor T4 may be connected to the third scan line GIL. A first terminal of the fourth transistor T4 may be connected to the first initialization voltage line VIL1. A second terminal of the fourth transistor T4 may be connected to the first capacitor electrode CE1 of the storage capacitor Cst, the first terminal of the third transistor T3, and the first gate electrode of the first transistor T1. The fourth transistor T4 may be turned on according to a third scan signal GI transferred through the third scan line GIL and may perform an initialization operation to initialize the voltage of the first gate electrode of the first transistor T1 by transferring the first initialization voltage Vint to the first gate electrode of the first transistor T1.

The fifth transistor T5 may be an operation control transistor. A fifth gate electrode of the fifth transistor T5 may be connected to the emission control line EML, a first terminal of the fifth transistor T5 may be connected to the driving voltage line PL, and a second terminal of the fifth transistor T5 may be connected to the first terminal of the first transistor T1 and the second terminal of the second transistor T2.

The sixth transistor T6 may be an emission control transistor. A sixth gate electrode of the sixth transistor T6 may be connected to the emission control line EML, a first terminal of the sixth transistor T6 may be connected to the second terminal of the first transistor T1 and the second terminal of the third transistor T3, and a second terminal of the sixth transistor T6 may be electrically connected to a second terminal of the seventh transistor T7 and the pixel electrode (e.g., anode) of the organic light-emitting diode OLED.

The fifth transistor T5 and the sixth transistor T6 may be simultaneously turned on according to an emission control signal EM transferred through the emission control line EML, the first power voltage ELVDD may be transferred to the organic light-emitting diode OLED, and the driving current I_{d} may flow through the organic light-emitting diode OLED.

The seventh transistor T7 may be a second initialization transistor that initializes the pixel electrode of the organic light-emitting diode OLED. A seventh gate electrode of the seventh transistor T7 may be connected to the fourth scan line GBL. A first terminal of the seventh transistor T7 may be connected to the second initialization voltage line VIL2. A second terminal of the seventh transistor T7 may be connected to the second terminal of the sixth transistor T6 and the pixel electrode (e.g., anode) of the organic light-emitting diode OLED. The seventh transistor T7 may be turned on according to a fourth scan signal GB transferred through the fourth scan line GBL, and initialize the pixel electrode of the organic light-emitting diode OLED by transferring the second initialization voltage Vaint to the pixel electrode (e.g., anode) of the organic light-emitting diode OLED.

A fourth scan signal GB may be substantially synchronized with a first scan signal GW. In an embodiment, a fourth scan signal GB may be substantially synchronized with a first scan signal GW of a pixel in a next row. As an example, the fourth scan line GBL may be substantially the same as the first scan line GWL of a pixel in a next row.

The storage capacitor Cst may include the first capacitor electrode CE1 and a second capacitor electrode CE2. The first capacitor electrode CE1 of the storage capacitor Cst may be connected to the first gate electrode of the first transistor T1, and the second capacitor electrode CE2 of the storage capacitor Cst may be connected to the driving voltage line PL. In an embodiment, the first capacitor electrode CE1 of the storage capacitor Cst may be integral with the first gate electrode of the first transistor T1. The storage capacitor Cst may store charge corresponding to a difference between a voltage of the first gate electrode of the first transistor T1 and the first power voltage ELVDD.

The boost capacitor Cbt may include a third capacitor electrode CE3 and a fourth capacitor electrode CE4. The third capacitor electrode CE3 may be connected to the second gate electrode of the second transistor T2 and the first scan line GWL, and the fourth capacitor electrode CE4 may be connected to the first terminal of the third transistor T3 and the node connection line 166. In case that a first scan signal GW supplied to the first scan line GWL is a turn-off voltage, the boost capacitor Cbt may raise the voltage of a first node N1 to clearly express a black grayscale. The first node N1 may be a region where the first gate electrode of the first transistor T1, the first terminal of the third transistor T3, the second terminal of the fourth transistor T4, and the fourth capacitor electrode CE4 of the boost capacitor Cbt are connected to each other.

The pixel electrode (e.g., anode) of the organic light-emitting diode OLED may be electrically connected to the first transistor T1 through the sixth transistor T6. The opposite electrode (e.g., cathode) of the organic light-emitting diode OLED may be electrically connected to the common voltage line VSL, and may receive a voltage corresponding to a second power voltage ELVSS through the common voltage line VSL.

In an embodiment, some transistors among the first to seventh transistors T1, T2, T3, T4, T5, T6, and T7 may be n-channel metal oxide semiconductor field-effect transistors (MOSFETs), and the rest may be p-channel MOSFETs. In an embodiment, as shown in FIG. 2, the third and fourth transistors T3 and T4 may be n-channel MOSFETs, and the first, second, and fifth to seventh transistors T1, T2, T5, T6, and T7 may be p-channel MOSFETs.

A transistor including a silicon semiconductor layer may have a high electron mobility and excellent reliability. Accordingly, because the first transistor T1 directly influencing the brightness of the organic light-emitting diode OLED includes a silicon semiconductor layer, the display apparatus of high resolution may be implemented.

A transistor including an oxide semiconductor layer may have a low off-current and may be driven at low frequencies. Accordingly, because at least one of the remaining transistors T2, T3, T4, T5, T6, and T7 other than the first transistor T1 includes an oxide semiconductor layer, the power consumption of the display apparatus may be reduced.

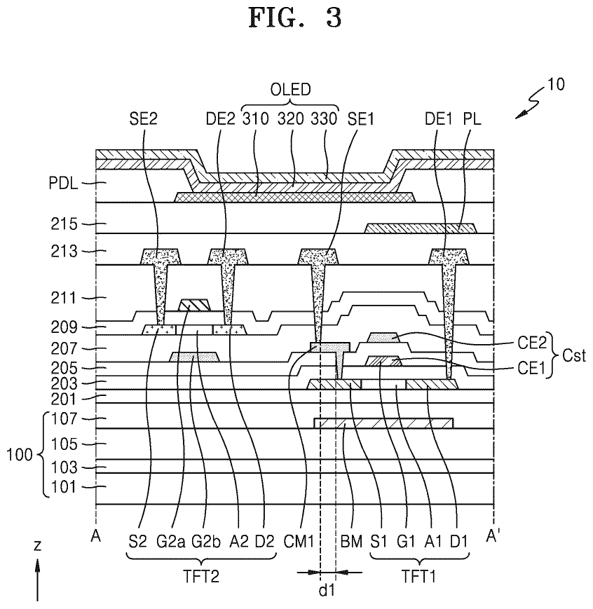

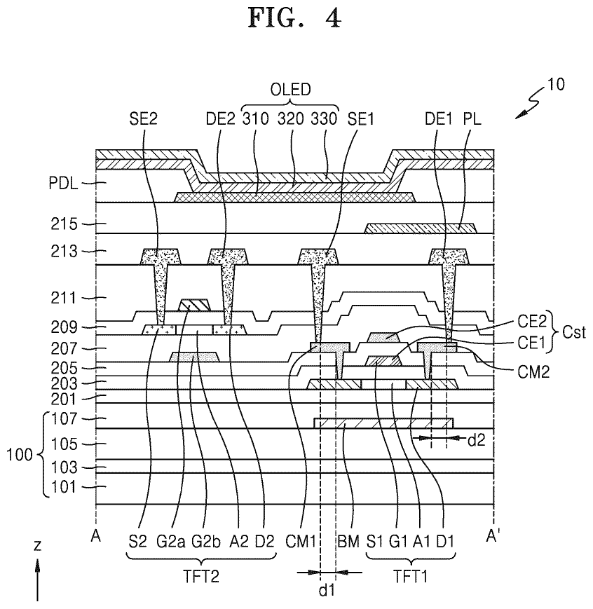

FIGS. 3 and 4 are schematic cross-sectional views of a display apparatus 10 according to an embodiment. FIG. 3 shows a cross-section of the display apparatus 10 shown in FIG. 1, taken along line A-A′ of the display apparatus 10 in FIG. 1, and FIG. 4 shows a modified embodiment of a cross-section of the display apparatus 10 shown in FIG. 1, taken along line A-A′.

Referring to FIG. 3, the substrate 100 may include a glass material, a ceramic material, metal, plastic, or a flexible or bendable material.

The substrate 100 may have a single-layered structure or a multi-layered structure formed of the above materials, and may further include an inorganic layer in the case of the multi-layered structure. As an example, the substrate 100 may include a first organic base layer 101, a first inorganic barrier layer 103, a second organic base layer 105, and a second inorganic barrier layer 107. The first organic base layer 101 and the second organic base layer 105 may each include a polymer resin. The first inorganic barrier layer 103 and the second inorganic barrier layer 107 may function as barrier layers preventing the penetration of external foreign materials, and may include a single layer or a multi-layer including an inorganic insulating material such as silicon nitride and/or silicon oxide.

A bottom metal layer BM may be disposed between the second organic base layer 105 and the second inorganic barrier layer 107. In an embodiment, the bottom metal layer BM may be disposed between the second inorganic barrier layer 107 and a buffer layer 201. The bottom metal layer BM may include at least one material among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In an embodiment, the bottom metal layer BM may have a molybdenum-single layer, a double-layered structure in which a molybdenum layer and a titanium layer are stacked, or a triple-layered structure in which a titanium layer, an aluminum layer, and a titanium layer are stacked.

The buffer layer 201 may be disposed on the bottom metal layer BM. The buffer layer 201 may include an inorganic insulating layer including an inorganic insulating material such as silicon nitride and/or silicon oxide, and include a single layer structure or a multi-layered structure including the above material. The buffer layer 201 may increase the flatness of the upper surface of the substrate 100 and prevent or reduce the penetration (or permeation) of impurities from the substrate 100 and the like into a semiconductor layer.

A silicon-based semiconductor layer of silicon-based transistors may be disposed on the buffer layer 201. With regard to this, FIG. 3 shows a first active region A1, a first source region S1, and a first drain region D1 of a first thin-film transistor TFT1 corresponding to a portion of the silicon-based semiconductor layer. The first thin-film transistor TFT1 may function as a driving transistor and may have a configuration corresponding to the first transistor T1 described with reference to FIG. 2. The first source region S1 and the first drain region D1 may be disposed on sides (e.g., opposite sides) of the first active region A1 and may be doped regions doped with impurities.

A first gate insulating layer 203 (or first insulating layer) may be disposed on the silicon-based semiconductor layer. The first gate insulating layer 203 may include an inorganic insulating layer including an inorganic insulating material such as silicon oxide, silicon nitride and/or silicon oxynitride, and include a single layer structure or a multi-layered structure including the above material.

A first gate electrode G1 and/or the first capacitor electrode CE1 may be disposed on the first gate insulating layer 203. The first gate electrode G1 may be arranged to overlap the first active region A1. In the doping process of forming the first source region S1 and the first drain region D1, the first active region A1 overlapping the first gate electrode G1 may not be doped. In an embodiment, the first gate electrode G1 and/or the first capacitor electrode CE1 may be integral with each other. The first gate electrode G1 and/or the first capacitor electrode CE1 may include aluminum (Al), platinum (Pt), palladium (Pd), silver (Ag), magnesium (Mg), gold (Au), Nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

A second gate insulating layer 205 (or second insulating layer) may be disposed on the first gate electrode G1 and/or the first capacitor electrode CE1. The second gate insulating layer 205 may include an inorganic insulating layer including an inorganic insulating material such as silicon oxide, silicon nitride and/or silicon oxynitride, and include a single layer structure or a multi-layered structure including the above material.

The second capacitor electrode CE2, a first connection electrode CM1, and a second lower gate electrode G2b may be disposed on the second gate insulating layer 205. The second capacitor electrode CE2 may be arranged to overlap the first gate electrode G1 and/or the first capacitor electrode CE1. The first capacitor electrode CE1 and the second capacitor electrode CE2 may form the storage capacitor Cst.

The first connection electrode CM1 may be connected (e.g., electrically connected) to the first source region S1 through a first contact hole. As an example, the first connection electrode CM1 may be in contact with (e.g., in direct contact with) the first source region S1 through the first contact hole passing through the first gate insulating layer 203 and the second gate insulating layer 205 and exposing a portion of the first source region S1 of the first thin-film transistor TFT1.

The second capacitor electrode CE2, the first connection electrode CM1, and the second lower gate electrode G2b may each include aluminum (Al), platinum (Pt), palladium (Pd), silver (Ag), magnesium (Mg), gold (Au), Nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

A first interlayer insulating layer 207 (or third insulating layer) may be disposed on the second capacitor electrode CE2, the first connection electrode CM1, and the second lower gate electrode G2b. The first interlayer insulating layer 207 may include an inorganic insulating layer including an inorganic insulating material such as silicon oxide, silicon nitride and/or silicon oxynitride, and include a single layer structure or a multi-layered structure including the above material.

An oxide-based semiconductor layer may be disposed on the first interlayer insulating layer 207. With regard to this, FIG. 3 shows a second active region A2, a second source region S2, and a second drain region D2 of a second thin-film transistor TFT2 corresponding to a portion of the oxide-based semiconductor layer. The second thin-film transistor TFT2 may be an element corresponding to one of the third transistor T3 and the fourth transistor T4 described with reference to FIG. 2. The second source region S2 and the second drain region D2 may be disposed on sides (e.g., opposite sides) of the second active region A2 and may be doped regions doped with impurities. The second active region A2 may be arranged to overlap a second lower gate electrode G2b.

A third gate insulating layer 209 (or fourth insulating layer) may be disposed on the oxide-based semiconductor layer. Although it is shown in FIG. 3 that the third gate insulating layer 209 is formed to cover the substrate 100 entirely, embodiments are not limited thereto. In an embodiment, the third gate insulating layer 209 may be disposed only between a second upper gate electrode G2a and the second active region A2.

The third gate insulating layer 209 may include an inorganic insulating layer including an inorganic insulating material such as silicon oxide, silicon nitride and/or silicon oxynitride, and include a single layer structure or a multi-layered structure including the above material.

The second upper gate electrode G2a may be disposed on the third gate insulating layer 209. The second upper gate electrode G2a may be arranged to overlap the second active region A2. The second upper gate electrode G2a and the second lower gate electrode G2b may be disposed to face each other with the second active region A2 between the second upper gate electrode G2a and the second lower gate electrode G2b, and the width of the second upper gate electrode G2a may be less than the width of the second lower gate electrode G2b. In an embodiment, one of the second upper gate electrode G2a and the second lower gate electrode G2b may be omitted.

The second upper gate electrode G2a may include aluminum (Al), platinum (Pt), palladium (Pd), silver (Ag), magnesium (Mg), gold (Au), Nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

The second interlayer insulating layer 211 (or fifth insulating layer) may be disposed on the second upper gate electrode G2a. The second interlayer insulating layer 211 may include an inorganic insulating layer including an inorganic insulating material such as silicon oxide, silicon nitride and/or silicon oxynitride, and include a single layer structure or a multi-layered structure including the above material.

Source-drain electrodes may be disposed on the second interlayer insulating layer 211. The source-drain electrodes may be connected (e.g., electrically connected) to a portion of the silicon-based semiconductor layer and/or a portion of the oxide-based semiconductor layer. The source-drain electrodes may include a first source electrode SE1 connected (e.g., electrically connected) to the first source region S1 of the first thin-film transistor TFT1, a first drain electrode DE1 connected (e.g., electrically connected) to the first drain region D1 of the first thin-film transistor TFT1, a second source electrode SE2 connected (e.g., electrically connected) to the second source region S2 of the second thin-film transistor TFT2, and a second drain electrode DE2 connected (e.g., electrically connected) to the second drain region D2 of the second thin-film transistor TFT2. For example, a source electrode of one thin-film transistor may function as a drain electrode of an adjacent thin-film transistor. As an example, the first source electrode SE1 of the first thin-film transistor TFT1 may function as a drain electrode of another thin-film transistor that shares the first source region S1 with the first thin-film transistor TFT1. In an embodiment, at least one of the first source electrode SE1, the first drain electrode DE1, the second source electrode SE2, and the second drain electrode DE2 may be omitted.

The first source electrode SE1 of the first thin-film transistor TFT1 may be connected (e.g., electrically connected) to the first source region S1 of the first thin-film transistor TFT1 through the first connection electrode CM1. As an example, the first source electrode SE1 may be in contact with (e.g., in direct contact with) the first connection electrode CM1 through a second contact hole passing through the first interlayer insulating layer 207, the third gate insulating layer 209, and the second interlayer insulating layer 211, and exposing a portion of the first connection electrode CM1.

The first contact hole for electrically connecting the first connection electrode CM1 to the first source region S1 and the second contact hole for electrically connecting the first source electrode SE1 to the first connection electrode CM1 may be spaced apart from each other by a first distance d1. The first distance d1 may be a minimum distance on a straight line between the first contact hole and the second contact hole when viewed in a direction perpendicular to the substrate 100 (e.g., in a plan view). The first distance d1 may be about 1.0 μm to about 2.0 μm. In an embodiment, the first distance d1 may be about 1.8 μm. In case that the first distance d1 is less than about 1.0 μm, a defect due to an alignment mistake may occur during the manufacturing process of a contact hole, and in case that the first distance d1 is greater than about 2.0 μm, the area of the pixel circuit may increase and the resolution of the display apparatus may be reduced.

The source-drain electrodes may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

A first planarization layer 213 may be disposed on the first source electrode SE1, the first drain electrode DE1, the second source electrode SE2, and the second drain electrode DE2. The driving voltage line PL may be disposed on the first planarization layer 213. The driving voltage line PL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), and/or tungsten (W). In an embodiment, the driving voltage line PL may have a triple-layered structure of a titanium layer, an aluminum layer, and a titanium layer.

A second planarization layer 215 may be disposed on the driving voltage line PL. The first planarization layer 213 and the second planarization layer 215 may each include an organic insulating material such as benzocyclobutene (BCB), polyimide, or hexamethyldisiloxane (HMDSO).

The organic light-emitting diode OLED may be disposed on the second planarization layer 215. The organic light-emitting diode OLED may include a pixel electrode 310, an opposite electrode 330, and an intermediate layer 320 between the pixel electrode 310 and the opposite electrode 330 on the first planarization layer 213.

The pixel electrodes 310 may be reflective electrodes. In an embodiment, the pixel electrode 310 may include a reflective layer and a transparent or semi-transparent electrode layer on the reflective layer, the reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. The transparent electrode layer or semi-transparent electrode layer may include at least one of indium tin oxide, indium zinc oxide, zinc oxide, indium oxide, indium gallium oxide, and aluminum zinc oxide. In an embodiment, the pixel electrode 310 may have a three-layered structure of an indium tin oxide (ITO) layer, an Ag layer, and an ITO layer.

A pixel-defining layer PDL may be disposed on the pixel electrode 310 to cover the edge portions of the pixel electrodes 310. The pixel-defining layer PDL may define an opening exposing the upper surface of each of the pixel electrodes 310. An opening of the pixel-defining layer PDL may define an emission area of the organic light-emitting diode OLED. The pixel-defining layer PDL may cover the edge portions of the pixel electrode 310 and prevent arcs and the like from occurring at the edge portions of the pixel electrode 310 by increasing a distance between the edge portions of the pixel electrode 310 and the opposite electrode 330. The pixel-defining layer PDL may be formed by spin coating and the like using organic insulating materials such as polyimide, polyamide, acrylic resin, benzocyclobutene, hexamethyldisiloxane (HMDSO), and phenolic resin.

In an embodiment, the pixel-defining layer PDL may include a light-blocking material and be formed in black. The light-blocking material may include carbon black, carbon nanotubes, a resin or paste including black dye, metal particles, for example, nickel, aluminum, molybdenum, and an alloy thereof, metal oxide particles (e.g., chrome oxide) or metal nitride particles (e.g., chrome nitride). In the case where the pixel-defining layer PDL includes a light-blocking material, external light reflection by a metal structure arranged below the pixel-defining layer PDL may be reduced.

The intermediate layer 320 may include an emission layer patterned to correspond to the pixel electrode 310. The emission layer may include a low molecular weight organic material or a polymer organic material. A first common layer and/or a second common layer may be disposed under and on the emission layer. The first common layer may be disposed under the emission layer and may include, for example, a hole transport layer (HTL), or include an HTL and a hole injection layer (HIL). The second common layer may be disposed on the emission layer and may include an electron transport layer (ETL) and/or an electron injection layer (EIL). In an embodiment, the second common layer may not be provided. The emission layer may be patterned to correspond to the pixel electrode 310, and the first common layer and the second common layer may be common layers integrally formed to cover the organic light-emitting diodes OLED entirely.

The opposite electrode 330 may be a cathode which is an electron injection electrode. A metal, alloy, electrically conductive compound, or an arbitrary combination thereof having a low work function may be used as the opposite electrode 330. The opposite electrode 330 may be a transmissive electrode, a semi-transmissive electrode, or a reflective electrode.

The opposite electrode 330 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, indium zinc oxide (IZO), or any combination thereof. The opposite electrode 330 may have a single-layered structure, which is a single layer, or a multi-layered structure having a plurality of layers.

For example, the pixel electrode 310 may be formed for each organic light-emitting diode OLED, and the opposite electrode 330 may be integrally formed over the organic light-emitting diodes OLED. For example, the organic light-emitting diodes OLED may share the opposite electrode 330.

In an embodiment, a capping layer may be further disposed on the opposite electrode 330. The capping layer may improve an external light-emission efficiency of an organic light-emitting element based on a constructive interference principle. The capping layer may include a material having a refractive index of about 1.6 (at about 589 nm). The capping layer may be an organic capping layer including an organic material, an inorganic capping layer including an inorganic material, or a composite capping layer including an organic material and an inorganic material.

An encapsulation layer may be disposed on the organic light-emitting diode OLED. The encapsulation layer may include at least one inorganic encapsulation layer and at least one organic encapsulation layer. The inorganic encapsulation layer may include silicon oxide, silicon nitride, and/or silicon oxynitride, and the organic encapsulation layer may include an organic insulating material.

Before the first connection electrode CM1 and a second connection electrode CM2 are formed, the display apparatus 10 according to an embodiment may be manufactured by heat-treating a silicon-based semiconductor layer (e.g., the first semiconductor layer) after the first contact hole is formed. The characteristics of the first thin-film transistor TFT1 may be controlled by removing a hydrogen atom coupled to a dangling bond in a region adjacent to the first contact hole by the heat treatment. As an example, a driving range of a gate voltage of the first thin-film transistor TFT1 may be improved by the heat treatment.

In the case where the oxide-based semiconductor layer is exposed to the heat treatment process, hydrogen atoms may penetrate the oxide-based semiconductor layer and a threshold voltage of the second thin-film transistor TFT2 may be transited (shifted) in a negative direction. Accordingly, to prevent a threshold voltage transition (or shift) of the second thin-film transistor TFT2 due to the heat treatment process, before the oxide-based semiconductor layer is formed, the display apparatus 10 according to an embodiment may form the first contact hole passing through the first interlayer insulating layer 207 and the third gate insulating layer 209 and then perform heat treatment on the first source region S1 through the first contact hole. Accordingly, the second thin-film transistor TFT2 may be formed to have a high mobility of 30 cm²/V·s or more.

Although it is shown in FIG. 3 that the first connection electrode CM1 is formed in the first source region S1 of the first thin-film transistor TFT1, embodiments are not limited thereto. The first connection electrode CM1 may be in contact with (e.g., in direct contact with) the first drain region D1 through a contact hole passing through the first gate insulating layer 203 and the second gate insulating layer 205 and exposing a portion of the first drain region D1 of the first thin-film transistor TFT1. For example, the first source electrode SE1 may be connected (e.g., electrically connected) to the first source region S1 of the first thin-film transistor TFT1, and the first drain electrode DE1 may be connected (e.g., electrically connected) to the first drain region D1 through the first connection electrode CM1.

Referring to FIG. 4, a second connection electrode CM2 may be further disposed between the second gate insulating layer 205 and the first interlayer insulating layer 207 of the display apparatus 10. The second connection electrode CM2 may be connected (e.g., electrically connected) to the first drain region D1 through a third contact hole. As an example, the second connection electrode CM2 may be in contact with (e.g., in direct contact with) the first drain region D1 through a third contact hole passing through the first gate insulating layer 203 and the second gate insulating layer 205 and exposing a portion of the first drain region D1 of the first thin-film transistor TFT1. The second connection electrode CM2, the second capacitor electrode CE2, the first connection electrode CM1, and the second lower gate electrode G2b may be disposed on the same layer, and may include the same material.

The first drain electrode DE1 of the first thin-film transistor TFT1 may be connected (e.g., electrically connected) to the first drain region D1 of the first thin-film transistor TFT1 through the second connection electrode CM2. As an example, the first drain electrode DE1 may be in contact with (e.g., in direct contact with) the second connection electrode CM2 through a fourth contact hole passing through the first interlayer insulating layer 207, the third gate insulating layer 209, and the second interlayer insulating layer 211, and exposing a portion of the second connection electrode CM2.

The third contact hole for electrically connecting the second connection electrode CM2 to the first drain region D1 and the fourth contact hole for electrically connecting the first drain electrode DE1 to the second connection electrode CM2 may be spaced apart from each other by a second distance d2. When viewed in a direction perpendicular to the substrate 100, the second distance d2 may be a minimum distance on a straight virtual line between the third contact hole and the fourth contact hole. The second distance d2 may be about 1.0 μm to about 2.0 μm. In an embodiment, the second distance d2 may be about 1.8 μm.

Before the first connection electrode CM1 and the second connection electrode CM2 are formed, in the display apparatus 10 according to an embodiment, the heat treatment may be performed on the first source region S1 and the first drain region D1 after the first contact hole and the third contact hole is formed. The characteristics of the first thin-film transistor TFT1 may be improved by removing hydrogen atoms coupled to the dangling bonds of the first source region S1 and the first drain region D1 by the heat treatment. Because the oxide-based semiconductor layer is formed after the heat treatment of the silicon-based semiconductor layer, a threshold voltage transition (or shift) of the second thin-film transistor TFT2 due to the heat treatment may be reduced.

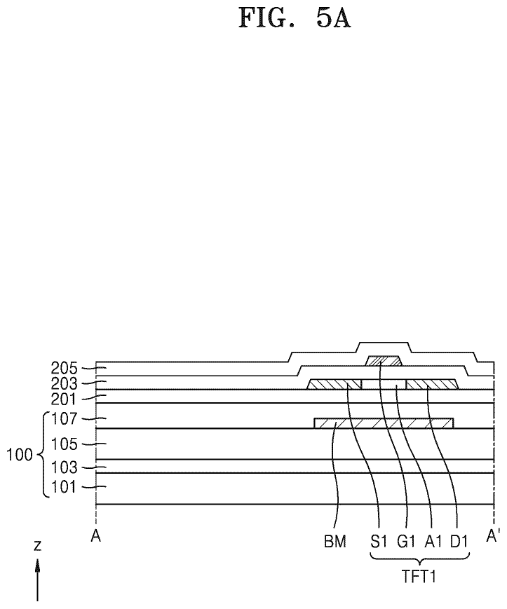

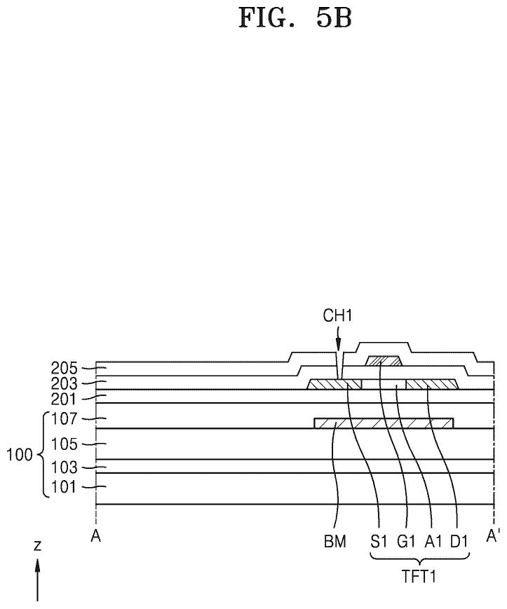

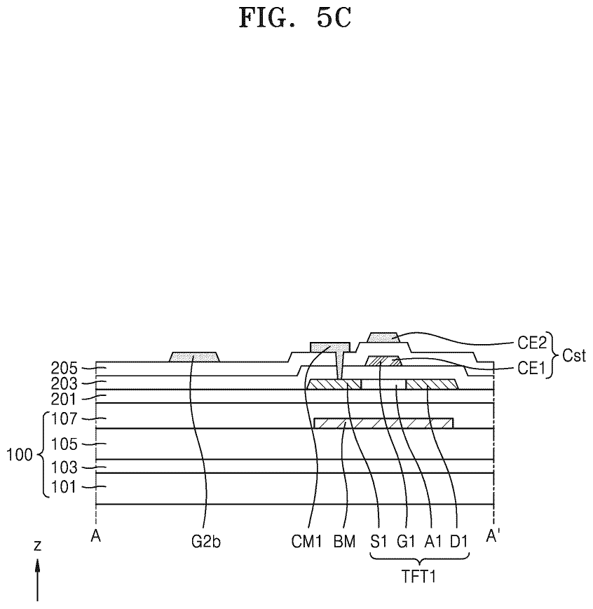

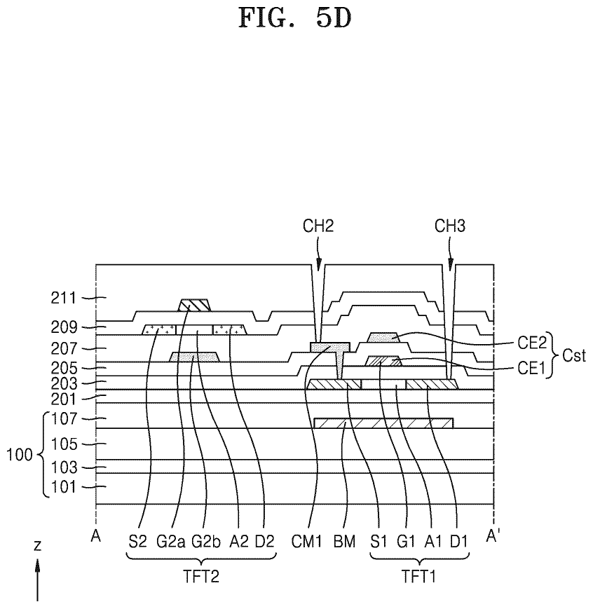

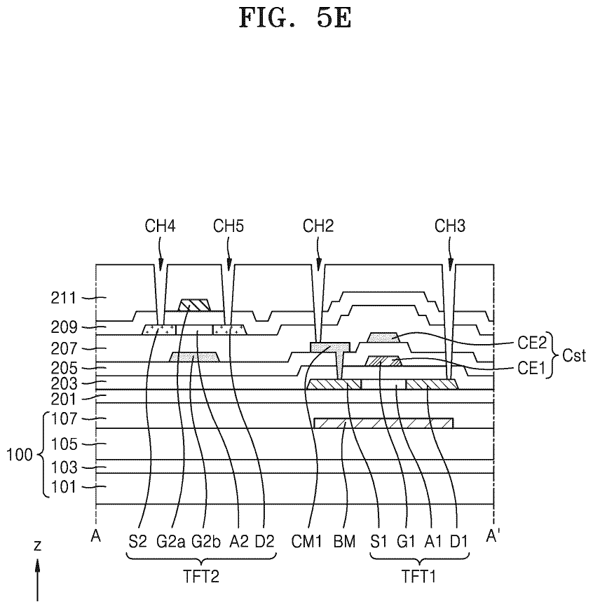

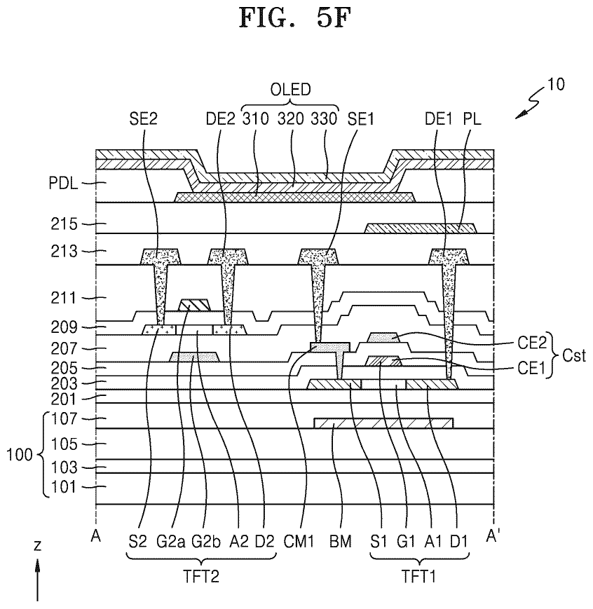

FIGS. 5A, 5B, 5C, 5D, 5E, and 5F are schematic cross-sectional views for explaining some of operations of a method of manufacturing a display apparatus according to an embodiment.

Referring to FIG. 5A, the silicon-based semiconductor layer (or first semiconductor layer) may be formed on the substrate 100. The substrate 100 may have a single-layered structure or a multi-layered structure. As an example, the substrate 100 may include a first organic base layer 101, a first inorganic barrier layer 103, a second organic base layer 105, and a second inorganic barrier layer 107.

In an embodiment, the bottom metal layer BM may be formed between the second organic base layer 105 and the second inorganic barrier layer 107. In another embodiment, the bottom metal layer BM may be formed between the second inorganic barrier layer 107 and a buffer layer 201. The bottom metal layer BM may be arranged to overlap the silicon-based semiconductor layer. As an example, when viewed in a direction perpendicular to the substrate 100, the first active region A1 of the silicon-based semiconductor layer may be positioned in the inner side of the bottom metal layer BM.

The first gate insulating layer 203 may be formed on the silicon-based semiconductor layer, and a first conductive layer may be formed on the first gate insulating layer 203. The first conductive layer may include the first gate electrode G1 overlapping the silicon-based semiconductor layer. After the first gate electrode G1 is formed, the first active region A1, the first source region S1, and the first drain region D1 of the first thin-film transistor TFT1 may be formed by doping the silicon-based semiconductor layer. The first active region A1 may be an undoped region disposed below (e.g., directly blow) the first gate electrode G1. One of doped regions formed on sides (e.g., opposite sides) of the first active region A1 may be the first source region S1 and the other may be the first drain region D1.

The second gate insulating layer 205 may be formed on the first gate electrode G1.

Referring to FIG. 5B, a first contact hole CH1 passing through the first gate insulating layer 203 and the second gate insulating layer 205 and exposing a portion of the silicon-based semiconductor layer may be formed. The exposed portion of the silicon-based semiconductor layer may be the first source region S1 of the first thin-film transistor TFT1. In another embodiment, the first contact hole CH1 may expose the first drain region D1 of the first thin-film transistor TFT1.

After the first contact hole CH1 is formed, the silicon-based semiconductor layer may be heat-treated. A heat treatment temperature may be about 280° C. to about 370° C. The electrical characteristics of the first thin-film transistor TFT1 may be controlled by curing the first active region A1 through the heat treatment and removing hydrogen atoms coupled to the dangling bond to form intended defects. As an example, the range of a gate voltage may be improved. The gate voltage may be changed in case that a current flowing through the first thin-film transistor TFT1 changes from 1 pA to about 10 nA by the heat treatment.

Referring to FIG. 5C, a second conductive layer may be formed on the second gate insulating layer 205. The second conductive layer may include the first connection electrode CM1, the second lower gate electrode G2b, and the second capacitor electrode CE2. The first connection electrode CM1 may overlap the first contact hole CH1, and be in contact with (e.g., in direct contact with) the first source region S1 through the first contact hole CH1.

The second capacitor electrode CE2 may overlap the first gate electrode G1. The first gate electrode G1 may be integral with the first capacitor electrode CE1. Accordingly, the first capacitor electrode CE1 and the second capacitor electrode CE2 may form the storage capacitor Cst. The storage capacitor Cst may overlap the first active region A1 of the first thin-film transistor TFT1.

Referring to FIG. 5D, the first interlayer insulating layer 207 may be formed on the second conductive layer, and the oxide-based semiconductor layer (e.g., second semiconductor layer) may be formed on the first interlayer insulating layer 207. The third gate insulating layer 209 may be formed on the oxide-based semiconductor layer, and a third conductive layer may be formed on the third gate insulating layer 209. The third conductive layer may include the second upper gate electrode G2a overlapping the oxide-based semiconductor layer. The second interlayer insulating layer 211 may be formed on the third conductive layer.

Although it is shown in FIG. 5D that the third gate insulating layer 209 is formed to cover the substrate 100 entirely, embodiments are not limited thereto. In an embodiment, the third gate insulating layer 209 may be disposed only between the second upper gate electrode G2a and the second active region A2 of the oxide-based semiconductor layer by forming the second upper gate electrode G2a and then etching a portion of the third gate insulating layer 209.

After the second upper gate electrode G2a is formed, the second active region A2, the second source region S2, and the second drain region D2 of the second thin-film transistor TFT2 may be formed by doping the oxide-based semiconductor layer. The second active region A2 may be an undoped region disposed below (e.g., directly blow) the second upper gate electrode G2a. One of doped regions formed on sides (e.g., opposite sides) of the second active region A2 may be the second source region S2 and the other may be the second drain region D2.

The second upper gate electrode G2a and the second lower gate electrode G2b may be disposed to face each other with the second active region A2 of the second thin-film transistor TFT2 between the second upper gate electrode G2a and the second lower gate electrode G2b. The second thin-film transistor TFT2 may have a double gate electrode structure in which gate electrodes are disposed over and blow the second active region A2. In an embodiment, the width of the second lower gate electrode G2b may be greater than the width of the second upper gate electrode G2a.

The second interlayer insulating layer 211 may be formed, and then, the second contact hole CH2 passing through the first interlayer insulating layer 207, the third gate insulating layer 209, and the second interlayer insulating layer 211 and exposing a portion of the first connection electrode CM1 may be formed, and a third contact hole CH3 passing through the first gate insulating layer 203, the second gate insulating layer 205, the first interlayer insulating layer 207, the third gate insulating layer 209, the second interlayer insulating layer 211, and exposing a portion of the first drain region D1 of the first thin-film transistor TFT1 may be formed. In an embodiment, the second contact hole CH2 and the third contact hole CH3 may be simultaneously formed.

Referring to FIG. 5E, a fourth contact hole CH4 and a fifth contact hole CH5 passing through the third gate insulating layer 209 and the second interlayer insulating layer 211, and exposing a portion of the oxide-based semiconductor layer may be formed. The fourth contact hole CH4 may expose a portion of the second source region S2 of the second thin-film transistor TFT2, and the fifth contact hole CH5 may expose a portion of the second drain region D2 of the second thin-film transistor TFT2. For example, to reduce a defect due to alignment mistake of the contact holes, the first contact hole CH1 and the second contact hole CH2 may be formed to be spaced apart from each other. As an example, a distance between the first contact hole CH1 and the second contact hole CH2 may be about 1.0 μm to about 2.0 μm. In an embodiment, a distance between the first contact hole CH1 and the second contact hole CH2 may be about 1.8 μm.

Although it is shown in FIGS. 5D and 5E that an operation of forming the fourth contact hole CH4 and the fifth contact hole CH5 is performed after an operation of forming the second contact hole CH2 and the third contact hole CH3, embodiments are not limited thereto. In an embodiment, the second contact hole CH2, the third contact hole CH3, the fourth contact hole CH4, and the fifth contact hole CH5 may be simultaneously formed. In the case where the second contact hole CH2, the third contact hole CH3, the fourth contact hole CH4, and the fifth contact hole CH5 are simultaneously formed, the number of masks required is reduced, and thus, manufacturing costs may be reduced.

Referring to FIG. 5F, a fourth conductive layer including the source-drain electrodes may be formed on the second interlayer insulating layer 211. The source-drain electrodes may include the first source electrode SE1 and the first drain electrode DE1 of the first thin-film transistor TFT1, and the second source electrode SE2 and the second drain electrode DE2 of the second thin-film transistor TFT2.

The first source electrode SE1 may overlap the second contact hole CH2 and be connected (e.g., electrically connected) to the first connection electrode CM1 through the second contact hole CH2. The first drain electrode DE1 may overlap the third contact hole CH3 and be connected (e.g., electrically connected) to the first drain region D1 of the first thin-film transistor TFT1 through the third contact hole CH3. The second source electrode SE2 may overlap the fourth contact hole CH4 and be connected (e.g., electrically connected) to the second source region S2 of the second thin-film transistor TFT2 through the fourth contact hole CH4. The second drain electrode DE2 may overlap the fifth contact hole CH5 and be connected (e.g., electrically connected) to the second drain region D2 of the second thin-film transistor TFT2 through the fifth contact hole CH5.

The first planarization layer 213 may be formed on the fourth conductive layer, and the driving voltage line PL may be formed on the first planarization layer 213. The second planarization layer 215 may be formed on the driving voltage line PL, and the organic light-emitting diode OLED and the pixel-defining layer PDL may be formed on the second planarization layer 215. The organic light-emitting diode OLED may include the pixel electrode 310, the intermediate layer 320, and the opposite electrode 330.

Although it is shown in FIGS. 5B to 5F that the first contact hole CH1 is formed to expose the first source region S1 of the first thin-film transistor TFT1, embodiments are not limited thereto. The first contact hole CH1 may be formed to expose the first drain region D1 of the first thin-film transistor TFT1, and for example, the first connection electrode CM1 overlapping the first contact hole CH1 may be connected (e.g., electrically connected) to the first drain electrode DE1.

For example, as described with reference to FIG. 4, a sixth contact hole may be simultaneously formed while the first contact hole CH1 is formed. The sixth contact hole may expose the first drain region D1 of the first thin-film transistor TFT1. For example, the second conductive layer may further include the second connection electrode overlapping the sixth contact hole, and the first drain electrode DE1 may be connected (e.g., electrically connected) to the second connection electrode.

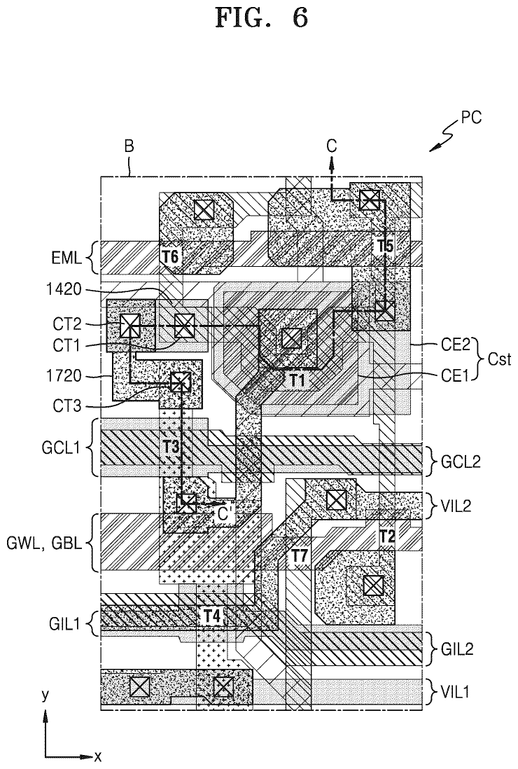

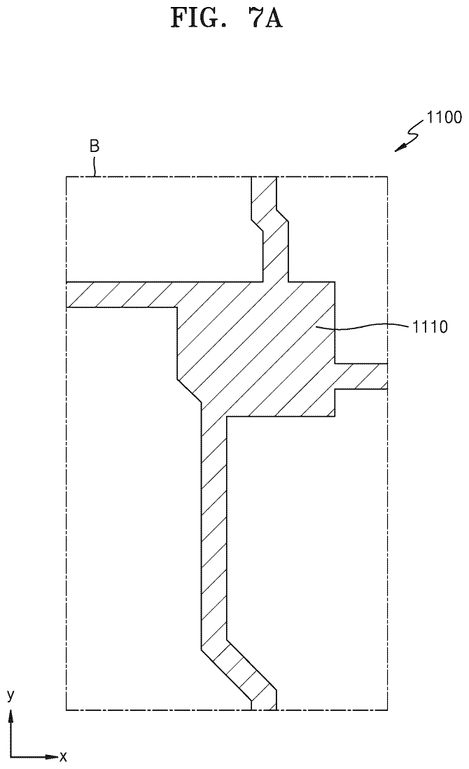

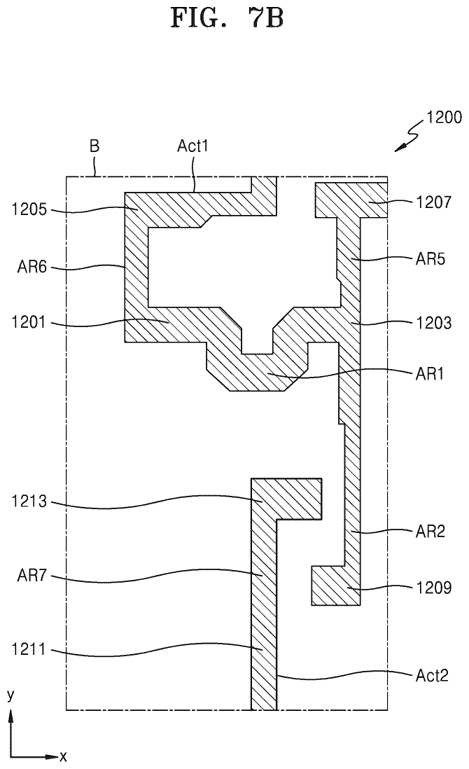

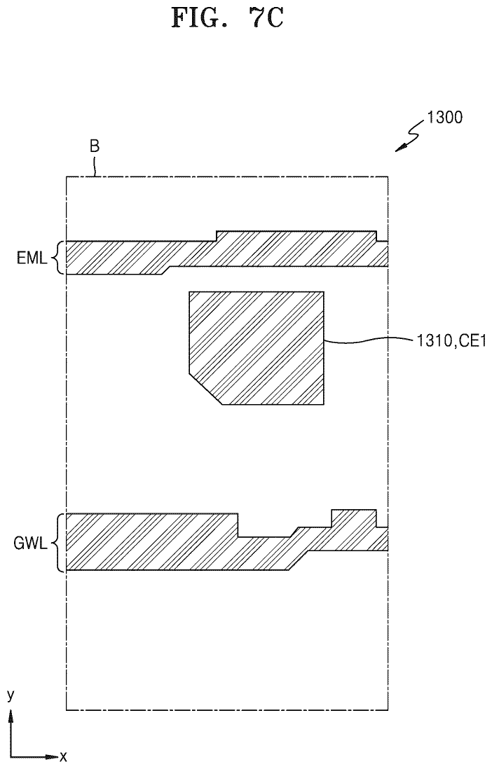

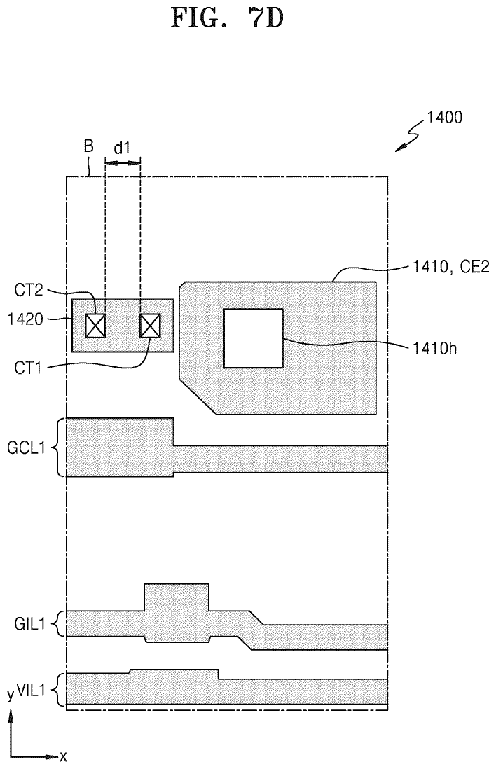

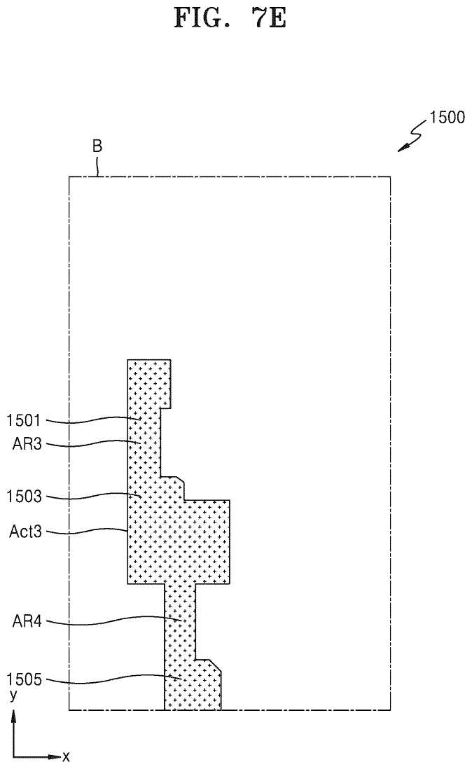

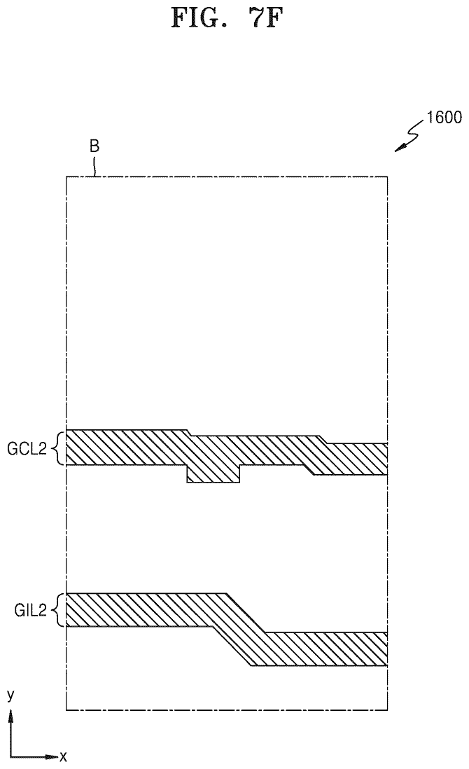

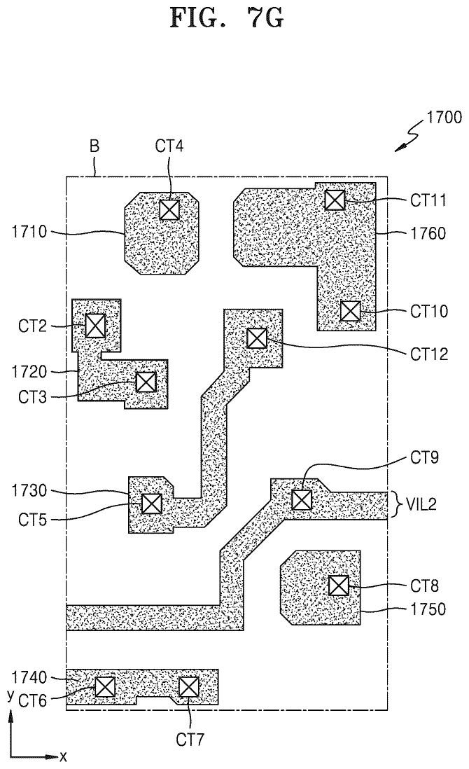

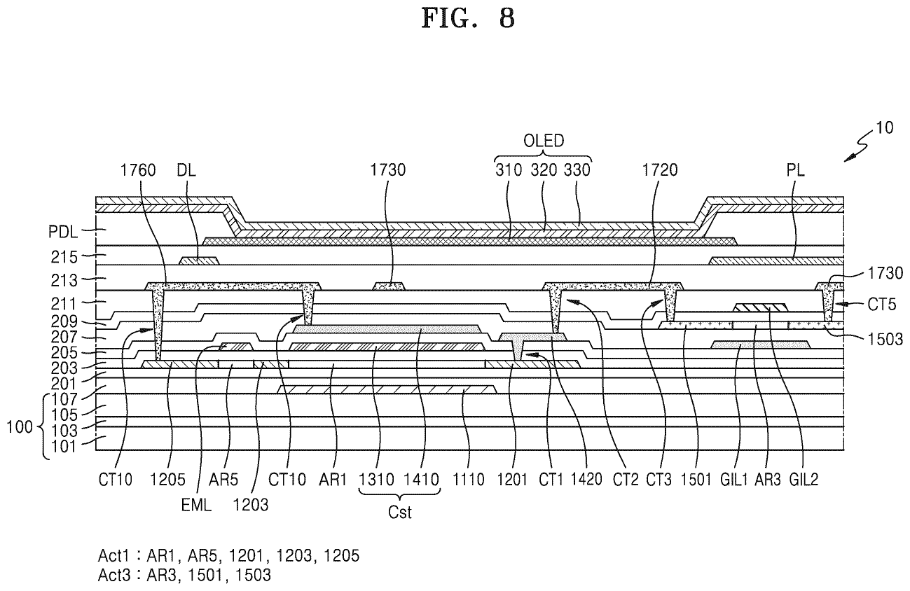

FIG. 6 is a schematic layout view of a display apparatus according to an embodiment illustrating an area B of FIG. 1, FIGS. 7A, 7B, 7C, 7D, 7E, 7F, and 7G are schematic layout views of a display apparatus for each layer according to an embodiment illustrating the area B of FIG. 1, and FIG. 8 is a schematic cross-sectional view of a display apparatus according to an embodiment. FIG. 8 shows a cross-section of the display apparatus shown in FIG. 6, taken along line C-C′ of FIG. 6.

Referring to FIGS. 6 and 7A to 7G, a pixel circuit PC may include T1, T2, T3, T4, T5, T6, and T7, and the storage capacitor Cst. The storage capacitor Cst may include the first capacitor electrode CE1 and the second capacitor electrode CE2, and the first capacitor electrode CE1 may function as the gate electrode of the first transistor T1. The first transistor T1 may be an element corresponding to the first thin-film transistor TFT1 described with reference to FIG. 3. As an example, the first transistor T1 may be a driving transistor.

Active regions AR1, AR2, AR5, AR6, and AR7 of the first transistor T1, the second transistor T2, the fifth transistor T5, the sixth transistor T6, and the seventh transistor T7 may be arranged along a first semiconductor pattern Act1 included in a first semiconductor layer 1200. The seventh transistor T7 shown in FIG. 6 is included in a pixel circuit positioned in an (n+1)-th row, and FIG. 7B shows a seventh active region AR7 (or sixth active portion) is arranged along a second semiconductor pattern Act2 included in the pixel circuit in the (n+1)-th row. Because pixel circuits having the same shape is repeatedly arranged, the seventh transistor T7 included in a pixel circuit PC positioned in an n-th row may be arranged in the first semiconductor pattern Act1. Here, n is a natural number.

The emission control line EML (or second conductive line) may extend in the first direction (e.g., x-axis direction) and may overlap the fifth active region AR5 (or fourth active portion) and the sixth active region AR6 (or second active portion) of the first semiconductor pattern Act1. In an embodiment, a portion of the emission control line EML overlapping the fifth active region AR5 may function as a gate electrode of the fifth transistor T5, and a portion of the emission control line EML overlapping the sixth active region AR6 may function as a gate electrode of the sixth transistor T6.

The first scan line GWL (or third conductive line) may extend in the first direction (e.g., x-axis direction) and may overlap the second active region AR2 (or fifth active portion) of the first semiconductor pattern Act1 and the seventh active region AR7 of the second semiconductor pattern Act2. The first scan line GWL may transfer a first scan signal GW (see FIG. 2). A portion of the first scan line GWL overlapping the second active region AR2 may function as a gate electrode of the second transistor T2. The first scan line GWL passing through the pixel circuit PC in the n-th row may function as the fourth scan line GBL (or fifth conductive line) passing through the pixel circuit PC in the (n+1)-th row. A portion of the fourth scan line GBL overlapping the seventh active region AR7 may function as a gate electrode of the seventh transistor T7.

The third transistor T3 and the fourth transistor T4 may be arranged along a third semiconductor pattern Act3 included in a second semiconductor layer 1500.

The second scan line GCL (see FIG. 2) may include a second-first scan line GCL1 (or fourth conductive line) and a second-second scan line GCL2 (or first conductive line) overlapping each other with the third active region AR3 (or upper-first active portion) of the third semiconductor pattern Act3 between the second-first scan line GCL1 and the second-second scan line GCL2. The second-first scan line GCL1 and the second-second scan line GCL2 may extend in the first direction (e.g., x-axis direction), and transfer a second scan signal GC (see FIG. 2).

A portion of the second-first scan line GCL1 may function as a lower gate electrode of the third transistor T3, and a portion of the second-second scan line GCL2 may function as an upper gate electrode of the third transistor T3. In a region adjacent to the third transistor T3, the width in the second direction (e.g., y-axis direction) of the second-first scan line GCL1 may be greater than the width in the second direction (e.g., y-axis direction) of the second-second scan line GCL2.

The third scan line GIL (see FIG. 2) may include a third-first scan line GIL1 and a third-second scan line GIL2 (or sixth conductive line) overlapping each other with the fourth active region AR4 (or upper-second active portion) of the third semiconductor pattern Act3 between the third-first scan line GIL1 and the third-second scan line GIL2. The third-first scan line GIL1 and the third-second scan line GIL2 may extend in the first direction (e.g., x-axis direction), and transfer a third scan signal GI (see FIG. 2).

A portion of the third-first scan line GIL1 may function as a lower gate electrode of the fourth transistor T4, and a portion of the third-second scan line GIL2 may function as an upper gate electrode of the fourth transistor T4. In a region adjacent to the fourth transistor T4, the width in the second direction (e.g., y-axis direction) of the third-first scan line GIL1 may be greater than the width in the second direction (e.g., y-axis direction) of the third-second scan line GIL2.

The first initialization voltage line VIL1 may extend in the first direction (e.g., x-axis direction) and be connected (e.g., electrically connected) to a tenth doped region 1505 of the third semiconductor pattern Act3. The second initialization voltage line VIL2 may extend in the first direction (e.g., x-axis direction) to overlap the third-second scan line GIL2 and be then refracted to be connected (e.g., electrically connected) to a seventh doped region 1213 of the second semiconductor pattern Act2.

Referring to FIGS. 7A and 8, the substrate 100 may include the first organic base layer 101, the first inorganic barrier layer 103, the second organic base layer 105, and the second inorganic barrier layer 107. A bottom metal layer 1100 may be disposed between the second organic base layer 105 and the second inorganic barrier layer 107. The bottom metal layer 1100 may include a main portion 1110 disposed under the first active region AR1 (or first active portion). The main portion 1110 may be connected to branch portions extending in the first direction (e.g., x-axis direction) and the second direction (e.g., y-axis direction).

The bottom metal layer 1100 may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials. The bottom metal layer 1100 may be, for example, a single layer of molybdenum, a double layer of molybdenum and titanium, or a triple layer of a titanium layer, an aluminum layer, and a titanium layer.

Referring to FIGS. 7B and 8, the buffer layer 201 may be disposed on the second inorganic barrier layer 107, and the first semiconductor layer 1200 may be disposed on the buffer layer 201. The first semiconductor layer 1200 may include the first semiconductor pattern Act1 and the second semiconductor pattern Act2. The first semiconductor layer 1200 may be a silicon-based semiconductor layer. The first semiconductor pattern Act1 may be a semiconductor pattern corresponding to a pixel circuit in an n-th row, and the second semiconductor pattern Act2 may be a semiconductor pattern corresponding to a pixel circuit in an (n+1)-th row. The first semiconductor layer 1200 may include the first active region AR1, the second active region AR2, the fifth active region AR5, the sixth active region AR6, and the seventh active region AR7, and doped regions may be disposed on sides (e.g., opposite sides) of each active region.

The first active region AR1 may be an active region of the first transistor T1, and may have a curved shape. Because the first active region AR1 has a curved shape (e.g., a curved shape of an omega shape) in a plan view, the first active region AR1 may form a long channel length within a narrow space. Accordingly, the first transistor T1 may more precisely control the grayscale of light emitted from the organic light-emitting diode OLED. The first active region AR1 may overlap the main portion 1110 of the bottom metal layer 1100.

A first doped region 1201 (or first doped portion) and a second doped region 1203 (or third doped portion) may be arranged on sides (e.g., opposite sides) of the first active region AR1. The first doped region 1201 may be arranged between the first active region AR1 and the sixth active region AR6, and the second doped region 1203 may be arranged between the first active region AR1 and the fifth active region AR5. The first doped region 1201 may be a drain region of the first transistor T1 and a source region of the sixth transistor T6. The second doped region 1203 may be a source region of the first transistor T1 and a drain region of the fifth transistor T5.

The second active region AR2 may be an active region of the second transistor T2. The second doped region 1203 and a fifth doped region 1209 (or fourth doped portion) may be arranged on sides (e.g., opposite sides) of the second active region AR2. For example, the second doped region 1203 may be arranged between the first active region AR1 and the second active region AR2. The fifth doped region 1209 may be an end portion of the first semiconductor pattern Act1 and may be connected (e.g., electrically connected) to the data line DL (see FIG. 2).

The fifth active region AR5 may be an active region of the fifth transistor T5. The second doped region 1203 and a fourth doped region 1207 may be arranged on sides (e.g., opposite sides) of the fifth active region AR5. The second doped region 1203 may be arranged between the first active region AR1 and the fifth active region AR5. The fourth doped region 1207 may be connected to a pixel circuit adjacent in the first direction (e.g., x-axis direction).

The sixth active region AR6 may be an active region of the sixth transistor T6. The first doped region 1201 and a third doped region 1205 may be arranged on sides (e.g., opposite sides) of the sixth active region AR6. The third doped region 1205 may have the same configuration as the sixth doped region 1211 of the second semiconductor pattern Act2. For example, the third doped region 1205 may be arranged between the sixth active region AR6 and the seventh active region AR7 of the first semiconductor pattern Act1.

The seventh active region AR7 may be an active region of the seventh transistor T7. A sixth doped region 1211 (or fifth doped portion) and a seventh doped region 1213 (or sixth doped portion) may be arranged on sides (e.g., opposite sides) of the seventh active region AR7. The seventh doped region 1213 may be an end portion of the second semiconductor pattern Act2, and may be connected (e.g., electrically connected) to the second initialization voltage line VIL2.

Referring to FIGS. 7C and 8, the first gate insulating layer 203 may be disposed on the first semiconductor layer 1200, and a first conductive layer 1300 may be disposed on the first gate insulating layer 203. The first conductive layer 1300 may include a first conductive pattern 1310, the emission control line EML, and the first scan line GWL (or fourth scan line GBL).

The first semiconductor layer 1200 may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

The first conductive pattern 1310 may have an isolated shape when viewed in a direction perpendicular to the substrate 100. The first conductive pattern 1310 may function as the gate electrode of the first transistor T1. The first conductive pattern 1310 may include the first capacitor electrode CE1. For example, the first conductive pattern 1310 and the first capacitor electrode CE1 may be integral with each other.

The first conductive pattern 1310 may be formed to cover the first active region AR1 of the first semiconductor pattern Act1 entirely. The main portion of the bottom metal layer 1100 may have a greater area than the first conductive pattern 1310.

The emission control line EML and the first scan line GWL may each extend in the first direction (e.g., x-axis direction). The emission control line EML and the first scan line GWL may be spaced apart from each other with the first conductive pattern 1310 between the emission control line EML and the first scan line GWL when viewed in a direction perpendicular to the substrate 100.

The emission control line EML may overlap the fifth active region AR5 and the sixth active region AR6 of the first semiconductor pattern Act1. A portion of the emission control line EML overlapping the fifth active region AR5 may function as the gate electrode of the fifth transistor T5, and a portion of the emission control line EML overlapping the sixth active region AR6 may function as the gate electrode of the sixth transistor T6. For example, the emission control line EML may include a gate electrode of the fifth transistor T5 and a gate electrode of the sixth transistor T6.

The first scan line GWL may overlap the second active region AR2 of the first semiconductor pattern Act1 and the seventh active region AR7 of the second semiconductor pattern Act2. A portion of the first scan line GWL overlapping the second active region AR2 may function as the gate electrode of the second transistor T2, and a portion of the first scan line GWL overlapping the seventh active region AR7 may function as the gate electrode of the seventh transistor T7. For example, the first scan line GWL may include a gate electrode of the second transistor T2 and a gate electrode of an (n+1)-th seventh transistor T7 in a next row.

Referring to FIGS. 7D and 8, the second gate insulating layer 205 may be disposed on the first conductive layer 1300, and a second conductive layer 1400 may be disposed on the second gate insulating layer 205. The second conductive layer 1400 may include a second conductive pattern 1410, a third conductive pattern 1420, the second-first scan line GCL1, the third-first scan line GIL1, and the first initialization voltage line VIL1.

The second conductive layer 1400 may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

The second conductive pattern 1410 may have an isolated shape when viewed in a direction perpendicular to the substrate 100. The second conductive pattern 1410 may overlap the first conductive pattern 1310 and include a hole 1410h exposing a portion of the first conductive pattern 1310. The second conductive pattern 1410 may include the second capacitor electrode CE2. For example, the second conductive pattern 1410 and the second capacitor electrode CE2 may be integral with each other. The first capacitor electrode CE1 and the second capacitor electrode CE2 may form the storage capacitor Cst.

The third conductive pattern 1420 may have an isolated shape when viewed in a direction perpendicular to the substrate 100. The third conductive pattern 1420 may be in contact with (e.g., in direct contact with) the first doped region 1201 through the first contact hole CT1 passing through the first gate insulating layer 203 and the second gate insulating layer 205 and exposing a portion of the first doped region 1201 of the first semiconductor pattern Act1. The third conductive pattern 1420 may be connected (e.g., electrically connected) to a fourth conductive pattern 1720 through the second contact hole CT2 passing through the first interlayer insulating layer 207, the third gate insulating layer 209, and the second interlayer insulating layer 211 and exposing a portion of the third conductive pattern 1420.

After the first contact hole CT1 is formed, and before the second conductive layer 1400 is formed, the first semiconductor layer 1200 may be heat-treated. A driving range of the gate voltage of the first transistor T1 may be improved by removing hydrogen atoms coupled to a dangling bond of a region adjacent to the first contact hole CT1 by the heat treatment. After the heat treatment, impurities may be prevented from penetrating the first semiconductor layer 1200 through the first contact hole CT1 during a subsequent process by covering the first contact hole CT1 with the third conductive pattern 1420.

The first contact hole CT1 may be spaced apart from the second contact hole CT2 by the first distance d1. The first distance d1 may be about 1.0 μm to about 2.0 μm. In the case where the first distance d1 is less than about 1.0 μm, a defect due to alignment mistake may occur during the manufacturing process of the contact holes. In the case where the first distance d1 is greater than about 2.0 μm, the area of the pixel circuit increases and the resolution of the display apparatus may be reduced.

The second-first scan line GCL1, the third-first scan line GIL1, and the first initialization voltage line VIL1 may each extend in the first direction (e.g., x-axis direction).

Referring to FIGS. 7E and 8, the first interlayer insulating layer 207 may be disposed on the second conductive layer 1400, and the second semiconductor layer 1500 may be disposed on the first interlayer insulating layer 207. The second semiconductor layer 1500 may be an oxide-based semiconductor layer. The second semiconductor layer 1500 may include the third semiconductor pattern Act3. The third semiconductor pattern Act3 may include a third active region AR3 (or upper-first active portion), a fourth active region AR4 (or upper-second active portion), and doped regions arranged on sides (e.g., opposite sides) of each of the active regions.

The third active region AR3 may be an active region of the third transistor T3. An eighth doped region 1501 (or second doped portion) and a ninth doped region 1503 (or seventh doped portion) may be arranged on sides (e.g., opposite sides) of the third active region AR3. The eighth doped region 1501 may be a drain region the third transistor T3 and may be connected (e.g., electrically connected) to the first doped region 1201, which is a drain region of the first transistor T1 through the second conductive pattern 1410 and the fourth conductive pattern 1720.

The fourth active region AR4 may be an active region of the fourth transistor T4. The eighth doped region 1501 and the ninth doped region 1503 may be arranged on sides (e.g., opposite sides) of the third active region AR3. For example, the ninth doped region 1503 may be arranged between the third active region AR3 and the fourth active region AR4. The ninth doped region 1503 may be a source region of the third transistor T3 and a drain region of the fourth transistor T4. In an embodiment, a portion of the ninth doped region 1503 overlapping the first scan line GWL may have a greater area than other regions. For example, a portion of the first scan line GWL and a portion of the ninth doped region 1503 overlapping each other may form the boost capacitor Cbt (see FIG. 2). The tenth doped region 1505 may be a source region of the fourth transistor T4 and may be connected (e.g., electrically connected) to the first initialization voltage line VIL1 through the seventh conductive pattern 1740.

Referring to FIGS. 7F and 8, the third gate insulating layer 209 may be disposed on the second semiconductor layer 1500, and a third conductive layer 1600 may be disposed on the third gate insulating layer 209. The third conductive layer 1600 may include the second-second scan line GCL2 and the third-second scan line GIL2. The second-second scan line GCL2 and the third-second scan line GIL2 may extend in the first direction (e.g., x-axis direction).

The third conductive layer 1600 may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

The second-second scan line GCL2 may overlap the third active region AR3 of the third semiconductor pattern Act3. A portion of the second-second scan line GCL2 overlapping the third active region AR3 may be an upper gate electrode of the third transistor T3. The second-second scan line GCL2 may overlap the second-first scan line GCL1. A portion of the second-first scan line GCL1 overlapping the third active region AR3 may be a lower gate electrode of the third transistor T3. For example, the third active region AR3 may be disposed between the second-first scan line GCL1 and the second-second scan line GCL2. The third transistor T3 may have a double gate electrode structure in which gate electrodes are respectively disposed in an upper portion and a lower portion thereof. In a region overlapping the third active region AR3, the width in the second direction (e.g., y-axis direction) of the second-first scan line GCL1 may be greater than the width in the second direction (e.g., y-axis direction) of the second-second scan line GCL2.

The third-second scan line GIL2 may overlap the fourth active region AR4 of the third semiconductor pattern Act3. A portion of the third-second scan line GIL2 overlapping the fourth active region AR4 may be an upper gate electrode of the fourth transistor T4. The third-second scan line GIL2 may overlap the third-first scan line GIL1. A portion of the third-first scan line GIL1 overlapping the fourth active region AR4 may be a lower gate electrode of the fourth transistor T4. For example, the fourth active region AR4 may be disposed between the third-first scan line GIL1 and the third-second scan line GIL2. The fourth transistor T4 may have a double gate electrode structure in which gate electrodes are respectively disposed in an upper portion and a lower portion thereof. In a region overlapping the fourth active region AR4, the width in the second direction (e.g., y-axis direction) of the third-first scan line GIL1 may be greater than the width in the second direction (e.g., y-axis direction) of the third-second scan line GIL2.

Referring to FIGS. 7G and 8, the second interlayer insulating layer 211 may be disposed on the third conductive layer 1600, and a fourth conductive layer 1700 may be disposed on the second interlayer insulating layer 211. The fourth conductive layer 1700 may include the fourth conductive pattern 1720, a fifth conductive pattern 1710, a sixth conductive pattern 1730, the seventh conductive pattern 1740, an eighth conductive pattern 1750, a ninth conductive pattern 1760, and the second initialization voltage line VIL2.

The fourth conductive layer 1700 may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

The fourth conductive pattern 1720 may be connected (e.g., electrically connected) to the third conductive pattern 1420 through the second contact hole CT2, and connected (e.g., electrically connected) to the eighth doped region 1501 of the third semiconductor pattern Act3 through a third contact hole CT3. For example, a drain region of the first transistor T1 may be connected (e.g., electrically connected) to a drain region of the third transistor T3 through the fourth conductive pattern 1720 and the third conductive pattern 1420.

The fifth conductive pattern 1710 may be connected (e.g., electrically connected) to the third doped region 1205 of the first semiconductor pattern Act1 through a fourth contact hole CT4. A drain region of the sixth transistor T6 may be connected (e.g., electrically connected) to the pixel electrode 310 of the organic light-emitting diode OLED through the fifth conductive pattern 1710.

The sixth conductive pattern 1730 may be connected (e.g., electrically connected) to the ninth doped region 1503 of the third semiconductor pattern Act3 through a fifth contact hole CT5, and connected (e.g., electrically connected) to the first conductive pattern 1310 through a twelfth contact hole CT12. When viewed in a direction perpendicular to the substrate 100, the twelfth contact hole CT12 may be positioned inside a hole 1410h of the second conductive pattern 1410, and the sixth conductive pattern 1730 may be connected (e.g., electrically connected) to the first conductive pattern 1310 exposed through the hole 1410h of the second conductive pattern 1410. A source region of the third transistor T3 may be connected (e.g., electrically connected) to the gate electrode of the first transistor T1 through the sixth conductive pattern 1730.

The seventh conductive pattern 1740 may be connected (e.g., electrically connected) to the first initialization voltage line VIL1 through a sixth contact hole CT6, and connected (e.g., electrically connected) to the tenth doped region 1505 of the third semiconductor pattern Act3 through a seventh contact hole CT7. A source region of the fourth transistor T4 may be connected (e.g., electrically connected) to the first initialization voltage line VIL1 through the seventh conductive pattern 1740.

The eighth conductive pattern 1750 may be connected (e.g., electrically connected) to the fifth doped region 1209 of the first semiconductor pattern Act1 through an eighth contact hole CT8. A source region of the second transistor T2 may be connected (e.g., electrically connected) to the data line DL through the eighth conductive pattern 1750.

The ninth conductive pattern 1760 may be connected (e.g., electrically connected) to the second conductive pattern 1410 of the second conductive layer 1400 through a tenth contact hole CT10, and may be connected (e.g., electrically connected) to the fourth doped region 1207 of the first semiconductor pattern Act1 through an eleventh contact hole CT11. A source region of the fifth transistor T5 and the second capacitor electrode CE2 of the storage capacitor Cst may be connected (e.g., electrically connected) to the driving voltage line PL through the ninth conductive pattern 1760.

The second initialization voltage line VIL2 may have a curved shape not to overlap the eighth conductive pattern 1750, and may extend in an approximately first direction (e.g., x-axis direction). The second initialization voltage line VIL2 may be connected (e.g., electrically connected) to a seventh doped region 1213 of the second semiconductor pattern Act2 through a ninth contact hole CT9.

Referring to FIG. 8, the first planarization layer 213 may be disposed on the fourth conductive layer 1700. The fifth conductive layer including the data line DL and the driving voltage line PL may be disposed on the first planarization layer 213. The fifth conductive layer may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

The second planarization layer 215 may be disposed on the fifth conductive layer. The organic light-emitting diode OLED may be disposed on the second planarization layer 215. The organic light-emitting diode OLED may include the pixel electrode 310, the opposite electrode 330, and the intermediate layer 320 between the pixel electrode 310 and the opposite electrode 330 on the first planarization layer 213.

For example, the pixel electrode 310 may be connected (e.g., electrically connected) to the fifth conductive pattern 1710 of the fourth conductive layer 1700 through a connection electrode disposed between the first planarization layer 213 and the second planarization layer 215.

Although it is shown in FIGS. 7A to 7G and 8 that the first contact hole CT1 exposes a portion of the first doped region 1201, and the third conductive pattern 1420 of the second conductive layer 1400 overlaps the first doped region 1201, embodiments are not limited thereto.

In an embodiment, the first contact hole CT1 may expose a portion of the second doped region 1203 of the first semiconductor pattern Act1, and the third conductive pattern 1420 of the second conductive layer 1400 may be formed to overlap the first contact hole CT1. The fourth conductive pattern 1720 of the fourth conductive layer 1700 may be in contact with (e.g., in direct contact with) the first doped region 1201 of the first semiconductor pattern Act1.

In another embodiment, the first contact hole CT1 and a thirteenth contact hole may be formed to respectively expose a portion of the first doped region 1201 and a portion of the second doped region 1203, and the second conductive layer 1400 may further include a conductive pattern overlapping the third conductive pattern 1420 and the thirteenth contact hole.

In the embodiments, because at least one contact hole exposing the source region and/or the drain region of the first transistor T1 is formed before the second semiconductor layer 1500 is formed, and the first semiconductor layer 1200 is heat-treated, a damage to the second semiconductor layer 1500 due to the heat treatment may be prevented. Accordingly, the display apparatus 10 with a narrower channel length of the second semiconductor layer 1500, which has a high electron mobility, and drivable at low power consumption, is provided.

The display apparatus having the above construction may be highly integrated and may provide high-quality images even when driven at high speeds. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first semiconductor layer disposed on the substrate and including a first active portion, a second active portion, and a first doped portion between the first active portion and the second active portion;
a first conductive layer disposed on the first semiconductor layer and including a first conductive pattern overlapping the first active portion;
a second conductive layer disposed on the first conductive layer and including a second conductive pattern and a third conductive pattern, the second conductive pattern overlapping the first conductive pattern, the third conductive pattern connected to the first doped portion through a first contact hole exposing a portion of the first doped portion;
a second semiconductor layer disposed on the second conductive layer and including an upper-first active portion and a second doped portion extending from the upper-first active portion;
a third conductive layer disposed on the second semiconductor layer and including a first conductive line overlapping the upper-first active portion; and
a fourth conductive layer disposed on the third conductive layer and including a fourth conductive pattern electrically connecting the third conductive pattern to the second doped portion.

2. The display apparatus of claim 1, wherein
the first semiconductor layer further includes a fourth active portion and a third doped portion between the first active portion and the fourth active portion, and
the first conductive layer further includes a second conductive line extending in a first direction and overlapping the second active portion and the fourth active portion.

3. The display apparatus of claim 2, wherein
the first semiconductor layer further includes a fifth active portion extending from the third doped portion to be farther away from the fourth active portion, and
the first conductive layer further includes a third conductive line extending in the first direction and overlapping the fifth active portion.

4. The display apparatus of claim 3, wherein
the first semiconductor layer further includes a fourth doped portion extending from the fifth active portion to be farther away from the third doped portion, and
the fourth doped portion is electrically connected to a data line.

5. The display apparatus of claim 1, wherein the second conductive layer further includes a fourth conductive line extending in a first direction and overlapping the upper-first active portion.

6. The display apparatus of claim 5, wherein the first conductive line and the fourth conductive line overlap each other.

7. The display apparatus of claim 1, wherein
the first semiconductor layer further includes a sixth active portion and a fifth doped portion and a sixth doped portion respectively extending to sides of the sixth active portion, and
the first conductive layer further includes a fifth conductive line extending in a first direction and overlapping the sixth active portion.

8. The display apparatus of claim 1, wherein
the second semiconductor layer further includes an upper-second active portion and a seventh doped portion between the upper-first active portion and the upper-second portion, and
the third conductive layer further includes a sixth conductive line extending in a first direction and overlapping the upper-second active portion.

9. The display apparatus of claim 1, wherein
the first semiconductor layer includes a silicon semiconductor material, and
the second semiconductor layer includes an oxide-based semiconductor material.

10. The display apparatus of claim 1, wherein
the fourth conductive pattern is connected to the third conductive pattern through a second contact hole exposing a portion of the third conductive pattern,
the first contact hole is spaced apart from the second contact hole by a first distance, and
the first distance is in a range of about 1 μm to about 2 μm.

11. A method of manufacturing a display apparatus, the method comprising:
forming a first semiconductor layer over a substrate;
forming a first insulating layer on the first semiconductor layer;
forming, on the first insulating layer, a first conductive layer including a first gate electrode overlapping the first semiconductor layer, and doping the first semiconductor layer;
forming a second insulating layer on the first conductive layer;
forming a first contact hole exposing a portion of the first semiconductor layer, and heat-treating the first semiconductor layer;
forming, on the second insulating layer, a capacitor electrode overlapping the first gate electrode and a second conductive layer including a first connection electrode overlapping the first contact hole;
forming a third insulating layer on the second conductive layer; and
forming a second semiconductor layer on the third insulating layer.

12. The method of claim 11, wherein
the first semiconductor layer includes a first active region, and a first doped region and a second doped region respectively extending to sides of the first active region, and
the first active region overlaps the first gate electrode, and
in the forming of the first contact hole and the heat-treating of the first semiconductor layer, the first contact hole is formed to overlap the first doped region.

13. The method of claim 12, further comprising:
forming a fourth insulating layer on the second semiconductor layer;
forming, on the fourth insulating layer, a third conductive layer including a second gate electrode overlapping the second semiconductor layer;
forming a fifth insulating layer on the third conductive layer;
forming a second contact hole, a third contact hole, and a fourth contact hole, the second contact hole exposing a portion of the first connection electrode, the third contact hole exposing a portion of the second doped region of the first semiconductor layer, and the fourth contact hole exposing a portion of the second semiconductor layer; and
forming, on the fifth insulating layer, a fourth conductive layer including a first source-drain electrode overlapping the second contact hole, a second source-drain electrode overlapping the third contact hole, a third source-drain electrode overlapping the fourth contact hole.

14. The method of claim 13, wherein the forming of the second contact hole, the third contact hole, and the fourth contact hole includes:
simultaneously forming the second contact hole and the third contact hole; and
after the forming of the second contact hole and the third contact hole, forming the fourth contact hole.

15. The method of claim 13, wherein the second contact hole, the third contact hole, and the fourth contact hole are simultaneously formed.

16. The method of claim 13, wherein
the first contact hole is spaced apart from the second contact hole by a first distance, and
the first distance is about 1 μm to about 2 μm.

17. The method of claim 12, wherein, in the forming of the first contact hole and the heat-treating of the first semiconductor layer, a fifth contact hole overlapping the second doped region is simultaneously formed with the first contact hole, and in the forming of the second conductive layer, the second conductive layer further includes a second connection electrode overlapping the fifth contact hole.

18. The method of claim 17, further comprising:
forming a fourth insulating layer covering the second semiconductor layer;
forming, on the fourth insulating layer, a third conductive layer including a second gate electrode overlapping the second semiconductor layer;
forming a fifth insulating layer on the third conductive layer;
forming a second contact hole exposing a portion of the first connection electrode, a third contact hole exposing a portion of the second connection electrode, and a fourth contact hole exposing a portion of the second semiconductor layer; and
forming, on the fifth insulating layer, a fourth conductive layer including a first source-drain electrode overlapping the second contact hole, a second source-drain electrode overlapping the third contact hole, and a third source-drain electrode overlapping the fourth contact hole.

19. The method of claim 18, wherein the second contact hole, the third contact hole, and the fourth contact hole are simultaneously formed.

20. The method of claim 11, wherein the first semiconductor layer includes a silicon semiconductor material, and the second semiconductor layer includes an oxide-based semiconductor material.
